(19) United States
(12) Patent Application Publication
(10) Pub. No.: US 2018/0331121 A1
(43) Pub. Date: Nov. 15, 2018

(54) SEMICONDUCTOR CHIP COMPRISING AN IOPAD FOR ELIMINATING ON-BOARD AND DISCRETE COMPONENTS

(71) Applicant: Nagesh H. Chatekar, Pune (IN)

(72) Inventor: Nagesh H. Chatekar, Pune (IN)

(21) Appl. No.: 15/831,605

(22) Filed: Dec. 5, 2017

(30) Foreign Application Priority Data
May 9, 2017 (IN) 201721016382

(51) Int. Cl. H01L 27/118; H01L 23/50; G06F 17/50; H03K 19/173; H03K 19/177; H03K 5/13

(52) U.S. Cl. CPC H01L 27/11898; H01L 23/50; H03K 5/13; H03K 19/1737; H03K 19/17744; G06F 17/5054

(57) ABSTRACT

An embodiment herein provides a semiconductor chip that includes an IOPAD. The IOPAD includes a core-side region. The core-side region includes one or more multiplexers. Each multiplexer is configured to electrically connect to an inverter and a delay balancing buffer. The multiplexer is configured to receive (i) an inverted input signal in an inverted signal path from the inverter, (ii) a non-inverted input signal in a non-inverted signal path from the delay balancing buffer and (iii) a control signal. The multiplexer selects the inverted input signal or the non-inverted input signal as an output signal to an output buffer or from an input buffer based on the control signal.

### CROSS-REFERENCE TO RELATED APPLICATIONS

This application claims priority to Indian patent application no. 201721016382 filed on May 9, 2017, the complete disclosure of which, in its entirely, is herein incorporated by reference.

### BACKGROUND

### Technical Field

The embodiments herein generally relate to integrated circuit design, and, more particularly, to a method for designing semiconductor chip with an IOPAD for eliminating on-board and discrete components.

### Description of the Related Art

The typical IOPAD design communicates with outside components in as-is form. There are situations where the communication needs to be modified at wire-speed before or after the on-chip logic circuitry. The typical IOPAD design requires discrete and on-board components to alter the communication at wire-speed. The typical IOPAD designs further do not have a capability of dynamically altering a behavior of the signal without the use of on-board and discrete components. These on-board and discrete components incur a huge-cost and a huge board space. This huge cost and the huge board space makes complexity for the designers to design a cheap, versatile and compact IOPAD design. Further, in typical IOPAD design, an impact of one IOPAD cannot be propagated into another IOPAD.

FIG. 1 illustrates a conventional IOPAD design of a semiconductor chip. The conventional IOPAD design includes a first buffer 102A, a second buffer 102B, a pull-down enable signal 114A and a pull-up enable signal 114B. The first buffer 102A is fed with a digital output signal 104 and a driving strength select signal 112 to provide a pad signal 116. The second buffer 102B is fed with an input buffer enable signal 108, a Schmitt trigger input buffer select signal 110 and a feedback signal 118 from output of the first buffer 102A to provide a digital input signal 106. The pull-down enable signal 114A and the pull-up enable signal 114B are adapted to control pull-up and pull-down characteristics of the semiconductor chip respectively. The Schmitt trigger input buffer select signal 110, the driving strength select signal 112 and the input buffer enable signal 108 are adapted to control the Schmitt trigger input buffer, driving strength and input buffer characteristics of the semiconductor chip respectively. The conventional IOPAD design requires external components such as the discrete and onboard components to dynamically alter the behavior of the signal and to balance time delay in the semiconductor chip.

Hence, there remains a need for designing a semiconductor chip circuit without on-board and discrete components to dynamically alter the behavior of the signal.

### SUMMARY

In the view of foregoing an embodiment herein provides a semiconductor chip that includes an IOPAD. The IOPAD includes a core-side region. The core-side region includes one or more multiplexers. The multiplexer is configured to electrically connect to an inverter and a delay balancing buffer. The multiplexer is configured to receive (i) an inverted input signal in an inverted signal path from the inverter, (ii) a non-inverted input signal in a non-inverted signal path from the delay balancing buffer and (iii) a control signal. The multiplexer selects the inverted input signal or the non-inverted input signal as an output signal into an output buffer or from an input buffer based on the control signal.

In one embodiment, the IOPAD further includes an interface-side-driver region configured to electrically connect to the core-side region to enable an interaction between the semi-conductor chip and a second IOPAD of a second semiconductor chip and to propagate impact of the IOPAD into the second IOPAD.

In another embodiment, the interface-side-driver region includes (a) the output buffer that receives the output signal from the multiplexers; and (b) the input buffer that communicates an input signal to the multiplexers. The output buffer and the input buffer are adapted to control the characteristics of the semiconductor chip. The characteristics of the semiconductor chip include at least one of (i) hysteresis, (ii) slew rate, (iii) pull-up-pull-down and (iv) drive strength.

In yet another embodiment, the IOPAD further includes an electrostatic discharge (ESD) protection diodes region.

In yet another embodiment, the semi-conductor chip is implemented in at least one application that comprises at least one of (i) a clock driver, or (ii) a LED driver circuit.

In yet another embodiment, the delay balancing buffer is electrically connected in parallel to the inverter to (a) obtain equivalent input output timing characteristics and (b) obtain similar IOPAD delay when signal passes through at least one of (i) the inverted signal path or (ii) the non-inverted signal path.

In yet another embodiment, the IOPAD is implemented in at least one of (a) a wire-bond type circuit or (b) a flip-chip type circuit.

In one aspect, a semiconductor chip includes a first IOPAD. The first IOPAD includes a core-side region. The core-side region includes one or more multiplexers. Each of the multiplexer is electrically connected to a gate array cell and a delay balancing buffer. The multiplexer is configured to receive (i) a modified input signal in a modified signal path from the gate array cell, (ii) a non-modified input signal in a non-modified signal path from the delay balancing buffer and (iii) a control signal. The multiplexer selects the modified input signal or the non-modified input signal as an output signal into an output buffer or from an input buffer based on the control signal. The gate array cell includes (i) a first gate array function selection input that selects a functionality of at least one logic gate to modify the input signal and (ii) a second gate array input that electrically connects with an input of a second IOPAD and drives the semiconductor chip under a new control signal.

In another aspect, a method for designing a semiconductor chip that includes an IOPAD includes steps of: (a) providing one or more multiplexers in a core-side region; (b) receiving, using each of the multiplexer, an inverted input signal in an inverted signal path from an inverter; (c) receiving, using the multiplexer, a non-inverted input signal in a non-inverted signal path from a delay balancing buffer; and (d) selecting, using the multiplexer, the inverted input signal or the non-inverted input signal as output signal to an output buffer or from an input buffer based on a control signal. The multiplexer is configured to electrically connect to the inverter. The multiplexer is configured to electrically connect to the delay balancing buffer.

This core-side region of the IOPAD with the one or more inverters or the one or more gate array cells dynamically alters a behaviour of an input signal with a fixed function and therefore reduces a bill of materials cost and board size for system designers. This concept of designing of the semiconductor chip further enables the system designers to build a cheap, compact and versatile IOPAD design in the semiconductor chip.

These and other aspects of the embodiments herein will be better appreciated and understood when considered in conjunction with the following description and the accompanying drawings. It should be understood, however, that the following descriptions, while indicating preferred embodiments and numerous specific details thereof, are given by way of illustration and not of limitation. Many changes and modifications may be made within the scope of the embodiments herein without departing from the spirit thereof, and the embodiments herein include all such modifications.

### BRIEF DESCRIPTION OF THE DRAWINGS

The embodiments herein will be better understood from the following detailed description with reference to the drawings, in which:

FIG. 1 illustrates a conventional IOPAD design of a semiconductor chip;

FIG. 2 is a schematic illustration of a semiconductor chip with an IOPAD according to a first embodiment herein;

FIG. 3 illustrates an exploded view of a core-side region of a semiconductor chip that includes one or more gate array cells according to a second embodiment herein; and

FIG. 4 illustrates a method for designing a semiconductor chip with an IOPAD according to an embodiment herein.

### DETAILED DESCRIPTION OF PREFERRED EMBODIMENTS

The embodiments herein and the various features and advantageous details thereof are explained more fully with reference to the non-limiting embodiments that are illustrated in the accompanying drawings and detailed in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

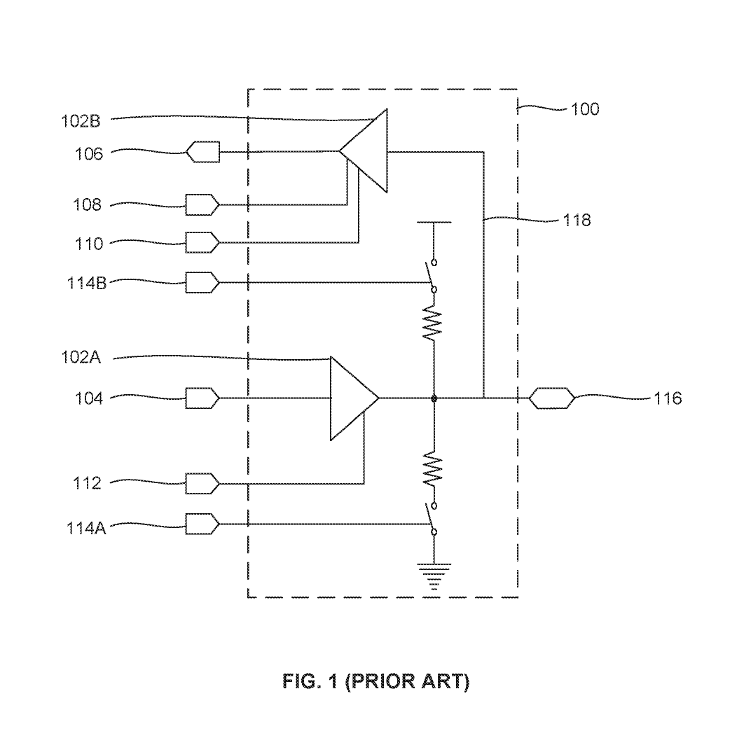

As mentioned, there remains a need for designing a semiconductor chip without on-board and discrete components to reduce cost and broad space. The embodiments herein achieve this by providing a semiconductor chip comprising an IOPAD with additional components inside a core-side logic region of the IOPAD. Referring now to the drawings, and more particularly to FIG. 1 through FIG. 4, where similar reference characters denote corresponding features consistently throughout the figures, there are shown preferred embodiments.

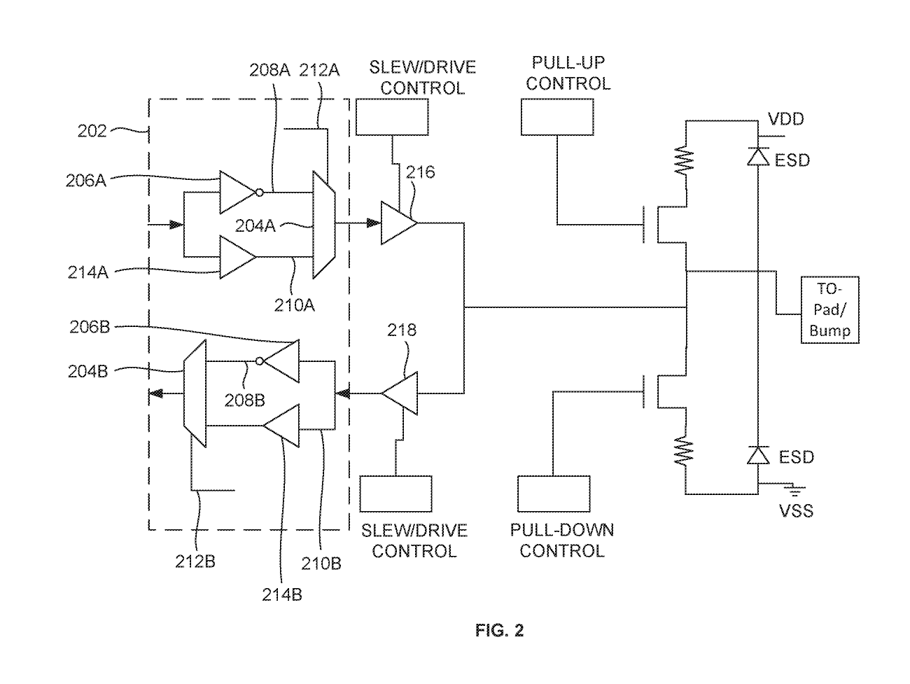

FIG. 2 is a schematic illustration of a semiconductor chip with an IOPAD according to a first embodiment herein. The semiconductor chip circuit includes the IOPAD. The IOPAD includes a core-side region 202. The core-side region 202 includes one or more multiplexers 204A-B, one or more inverters 206A-B and one or more delay balancing buffers 214A-B. The first multiplexer 204A is configured to electrically connect to the first inverter 206A and the first delay balancing buffer 214A. In an embodiment, the second multiplexer 204B is configured to electrically connect to the second inverter 206B and the second delay balancing buffer 214B. The first multiplexer 204A is configured to receive (i) a first inverted input signal in a first inverted signal path 208A from the first inverter 206A, (ii) a first non-inverted input signal in a first non-inverted signal path 210A from the first delay balancing buffer 214A and (iii) a first control signal 212A. The first multiplexer 204A selects the first inverted input signal or the first non-inverted input signal as an output signal into an output buffer 216 based on the control signal 212A. In an embodiment, the second multiplexer 204B is configured to receive (i) a second inverted input signal in a second inverted signal path 208B from the second inverter 206B, (ii) the second non-inverted input signal in a second non-inverted signal path 210B from the second delay balancing buffer 214B and (iii) a second control signal 212B. The second multiplexer 204B may select the second inverted input signal or the second non-inverted input signal as the output signal from an input buffer 218 based on the control signal 212B.

The one or more delay balancing buffers 214A-B are connected in parallel to the one or more inverters 206A-B to (a) obtain equivalent input output timing characteristics and (b) obtain similar IOPAD delay when the input signals (e.g. an inverted input signal, an non-inverted input signal) passes through at least one of (i) the one or more inverted signal paths 208A-B or (ii) the one or more non-inverted signal paths 210A-B.

The IOPAD further includes an interface-side-driver region. The interface-side-driver region is electrically connected to the core-side region 202 to enable an interaction between the semi-conductor chip and a second IOPAD of a second semiconductor chip to propagate impact of the IOPAD into the second IOPAD. The interface-side-driver region includes (i) the output buffer 216 that receives the output signal from the first multiplexer 204A and (ii) the input buffer 218 that communicates the input signal to the second multiplexer 204B. The output buffer 216 and the input buffer 218 are adapted to control characteristics of the semiconductor chip. The characteristics of the semiconductor chip include at least one of (i) hysteresis, (ii) slew rate, (iii) pull-up-pull-down or (iv) drive strength. The core-side region 202 may work on chip-level voltage (e.g. ˜1 volt (1 v) or less for 40 nm and below nodes) while the interface-side-driver region may work on interface voltage (e.g. 2.5 v, 3.3 v, 5.5 v etc.). The IOPAD further includes an electrostatic discharge (ESD) protection diodes region.

In one embodiment, the IOPAD is programmable for enabling or disabling at least one of (i) the inverted input signal or (ii) the non-inverted input signal. The semi-conductor chip is implemented in at least one application comprising at least one of (i) a clock driver, or (ii) a LED driver circuit. In an embodiment, the IOPAD is implemented in at least one of (a) a wire-bond type circuit or (b) a flip-chip type circuit. In another embodiment, the IOPAD is at least one of (i) a unidirectional IOPAD or (ii) a bi-directional IOPAD. The IOPAD also may be at least one of (i) an input type IOPAD, (ii) an output type IOPAD or (iii) an in-out type IOPAD.

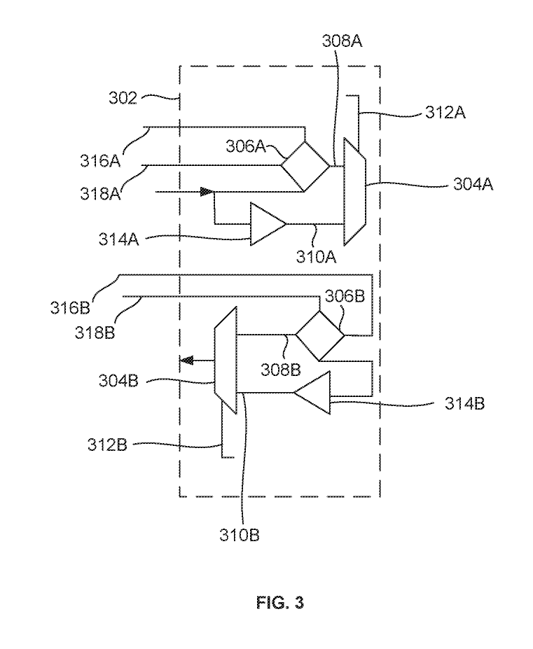

FIG. 3 illustrates an exploded view of a core-side region 302 of a semiconductor chip that includes one or more gate array cells 306A-B according to a second embodiment herein. The semiconductor chip includes a first IOPAD. The first IOPAD includes a core side region 302. The core side region 302 includes one or more multiplexers 304A-B, the one or more gate array cells 306A-B and one or more delay balancing buffers 314A-B. The first multiplexer 304A is configured to electrically connect to the first gate array cell 306A and the first delay balancing buffer 314A. The first multiplexer 304A is configured to receive (i) a first modified input signal in a first signal path 308A from the first gate array cell 306A, (ii) a first non-modified input signal in a second signal path 310A from the first delay balancing buffer 314A and (iii) a first control signal 312A. The first multiplexer 304A selects the first modified input signal or the first non-modified input signal as an output signal into an output buffer 316 based on the first control signal 312A. Similarly, in an embodiment, the second multiplexer 304B is configured to electrically connect to the second gate array cell 306B and the second delay balancing buffer 314B. The second multiplexer 304B may be configured to receive (i) a second modified input signal in a third signal path 308B from the second gate array cell 306B, (ii) a second non-modified input signal in a fourth signal path 310B from the second delay balancing buffer 314B and (iii) a second control signal 312B. The second multiplexer 304B may select the second modified input signal or the second non-modified input signal as the output signal from an input buffer 318 based on the second control signal 312B.

Each gate array cell (e.g. 306A and 306B) includes a first gate array function selection input (e.g. 316A and 316B) and a second gate array input (e.g. 318A and 318B). The first gate array function selection input 316 select a functionality of at least one logic gate within the semiconductor chip to modify the input signal and to obtain the modified input signal. In an embodiment, the first gate array function selection input 316 is adapted to select a functionality of at least one of AND, OR, XOR, buffer or NOT gate. The second gate array input 318 is electrically connected with an input of a second IOPAD and drives the semiconductor chip under a new control signal. In another embodiment, the first IOPAD and the second IOPAD is at least one of (i) a unidirectional IOPAD or (ii) a bi-directional IOPAD. The IOPAD also may be at least one of (i) an input type IOPAD, (ii) an output type IOPAD or (iii) an in-out type IOPAD.

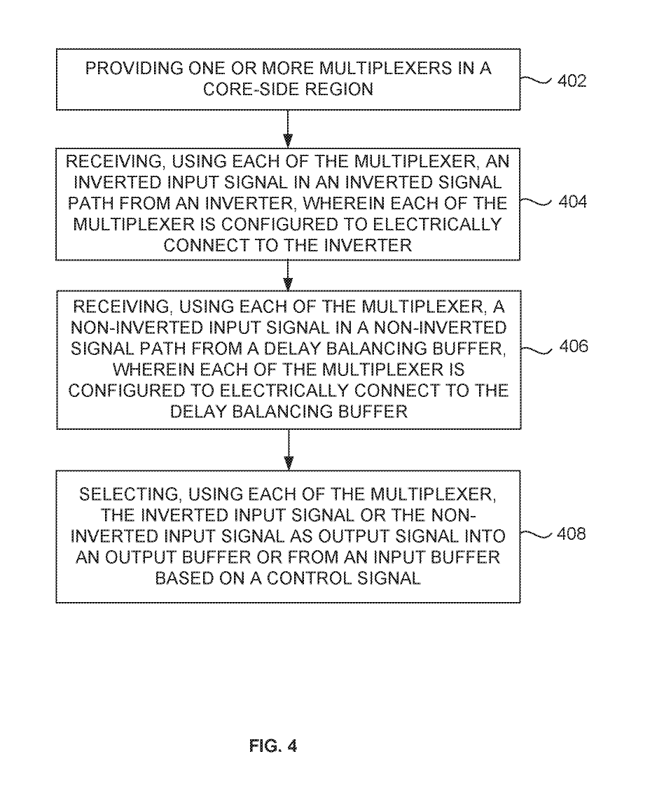

FIG. 4 illustrates a method for designing a semiconductor chip with an IOPAD according to an embodiment herein. At step 402, one or more multiplexers 204A-B is provided in a core-side region 202. At step 404, an inverted input signal is received in an inverted signal path 208 from an inverter 206 using the multiplexer 204. The multiplexer 204 is configured to electrically connect to the inverter 206. At step 406, a non-inverted input signal is received in a non-inverted signal path 210 from a delay balancing buffer 214. The multiplexer 204 is configured to electrically connect to the delay balancing buffer 214. At step 408, the inverted input signal or the non-inverted input signal is selected as an output signal into an output buffer 216 or from an input buffer 218 based on a control signal (e.g. a first control signal 212A or a second control signal 212B) using each of the multiplexer 204. The inverter 206 is connected in parallel to the delay balancing buffer 214 to (a) obtain equivalent input output timing characteristics and (b) obtain similar IOPAD delay when signal passes through at least one of (i) the inverted signal path 208 or (ii) the non-inverted signal path 210. In one embodiment, the IOPAD is at least one of (i) a unidirectional IOPAD or (ii) a bi-directional IOPAD. The IOPAD also may be at least one of (i) an input type IOPAD, (ii) an output type IOPAD or (iii) an in-out type IOPAD.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the appended claims.

What is claimed is:

1. A semiconductor chip comprising an IOPAD, the IOPAD comprising:
a core-side region, wherein the core-side region comprises
one or more multiplexers, wherein each of the multiplexer is configured to electrically connect to an inverter and a delay balancing buffer, wherein the multiplexer is configured to receive
an inverted input signal in an inverted signal path from the inverter,
a non-inverted input signal in a non-inverted signal path from the delay balancing buffer, and
a control signal,
wherein the multiplexer selects the inverted input signal or the non-inverted input signal as an output signal into an output buffer or from an input buffer based on the control signal.

2. The semiconductor chip of claim 1, wherein the IOPAD further comprises an interface-side-driver region configured to electrically connect to the core-side region to enable an interaction between the semi-conductor chip and a second IOPAD of a second semiconductor chip and to propagate impact of the IOPAD into the second IOPAD.

3. The semiconductor chip of claim 2, wherein the interface-side-driver region comprises
(a) the output buffer that receives the output signal from the multiplexers; and
(b) the input buffer that communicates an input signal to the multiplexers,
wherein the output buffer and the input buffer are adapted to control the characteristics of the semiconductor chip, wherein the characteristics of the semiconductor chip comprise at least one of (i) hysteresis, (ii) slew rate, (iii) pull-up-pull-down and (iv) drive strength.

4. The semiconductor chip of claim 1, wherein the IOPAD further comprises an electrostatic discharge (ESD) protection diodes region.

5. The semiconductor chip of claim 1, wherein the semi-conductor chip is implemented in at least one application that comprises at least one of (i) a clock driver, or (ii) a LED driver circuit.

6. The semiconductor chip of claim 1, wherein the delay balancing buffer is electrically connected in parallel to the inverter to (a) obtain equivalent input output timing characteristics and (b) obtain similar IOPAD delay when signal passes through at least one of (i) the inverted signal path or (ii) the non-inverted signal path.

7. The semiconductor chip of claim 1, wherein the IOPAD is programmable for enabling or disabling at least one of (i) the inverted input signal or (ii) the non-inverted input signal.

8. The semiconductor chip of claim 1, wherein the IOPAD is implemented in at least one of (a) a wire-bond type circuit or (b) a flip-chip type circuit.

9. A semiconductor chip comprising a first IOPAD, the first IOPAD comprising:
a core-side region, wherein the core-side region comprises:
one or more multiplexers, wherein each of the multiplexer is electrically connected to a gate array cell and a delay balancing buffer, wherein the multiplexer is configured to receive
a modified input signal in a first signal path from the gate array cell,
a non-modified input signal in a second signal path from the delay balancing buffer, and
a control signal,
wherein the multiplexer selects the modified input signal or the non-modified input signal as output signal into an output buffer or from an input buffer based on the control signal, wherein the gate array cell comprises
a first gate array function selection input that selects a functionality of at least one logic gate to modify the input signal; and
a second gate array input that electrically connects with an input of a second IOPAD and drives the semiconductor chip under a new control signal.

10. A method for designing a semiconductor chip comprising an IOPAD, wherein the designing comprising steps of:
providing one or more multiplexers in a core-side region;
receiving, using each of the multiplexer, an inverted input signal in an inverted signal path from an inverter, wherein the multiplexer is configured to electrically connect to the inverter;
receiving, using the multiplexer, a non-inverted input signal in a non-inverted signal path from a delay balancing buffer, wherein the multiplexer is configured to electrically connect to the delay balancing buffer; and
selecting, using the multiplexer, the inverted input signal or the non-inverted input signal as output signal to an output buffer or from an input buffer based on a control signal.
